(19) United States
(12) Patent Application Publication
(10) Pub. No.: US 2009/0244207 A1
(43) Pub. Date: Oct. 1, 2009

(54) LIQUID JET HEAD, A LIQUID JET APPARATUS AND A METHOD OF MANUFACTURING A LIQUID JET HEAD

(75) Inventor: Akihito Tsuda, Suwa-shi (JP)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: SEIKO EPSON CORPORATION, Shinjuku-ku (JP)

(21) Appl. No.: 12/406,891

(22) Filed: Mar. 18, 2009

(30) Foreign Application Priority Data
Mar. 18, 2008 (JP) 2008-068957

(51) Int. Cl. B41J 2/045; B05D 5/12; C23C 14/48

(52) U.S. Cl. 347/70; 427/100; 427/523

(57) ABSTRACT

A piezoelectric element includes a piezoelectric layer disposed between a first electrode and a second electrode. Anti-deformation layers continue from the piezoelectric layers ad contain a less moisture-permeable component than the piezoelectric layer. The piezoelectric layers and the anti-deformation layers are alternately and continuously disposed in the direction of the arrangement of the rows of the pressure generating chambers. The anti-deformation layers are disposed at least in regions opposing a partition member with the vibration plate therebetween. The piezoelectric layer is enclosed by the first electrode, the second electrode and at least either the vibration plate or the anti-deformation layer.

### CROSS REFERENCES TO RELATED APPLICATIONS

The present invention contains subject matter related to Japanese Patent Application No. 2008-68957 filed in the Japanese Patent Office on Mar. 18, 2008, the entire contents of which are incorporated herein by reference.

### BACKGROUND OF THE INVENTION

1. Field of the Invention

The present invention relates to a liquid jet head, a liquid jet apparatus and a method of manufacturing the same.

2. Description of the Related Art

A known ink jet recording head has a structure that includes a flow channel substrate having rows of pressure generating chambers communicating with nozzle apertures and a joining substrate bonded to the surface having a piezoelectric element of the flow channel substrate. The joining substrate also has a driving IC for driving the piezoelectric element.

The piezoelectric element includes an upper electrode, a piezoelectric layer and a lower electrode. The piezoelectric layer has a thickness as small as several micrometers. If moisture adheres to the sides of the piezoelectric layer or penetrates the piezoelectric layer, a short circuit or the like occurs undesirably between the upper electrode and the lower electrode.

For example, Japanese Unexamined Patent Application Publication No. 2007-281033 discloses that a protective film is provided to the piezoelectric element. In this structure, the protective film has a recess in the portion corresponding to the upper electrode so as to prevent the reduction in displacement of the vibration plate produced by driving the piezoelectric element.

If a protective film or the like is formed on the piezoelectric element, the protective film or the like affects the piezoelectric element to reduce the displacement of the vibration plate.

This problem arises not only in ink jet recording heads ejecting ink droplets, but also in other liquid jet heads ejecting droplets other than ink.

### SUMMARY OF THE INVENTION

Accordingly, the present invention has been made in order to solve at least part of the above problem, and the following embodiments of the invention can be achieved.

A liquid jet head according to an embodiment of the present invention includes: rows of pressure generating chambers communicating with respective nozzle apertures; a partition member separating the pressure generating chambers from each other; and piezoelectric elements opposing the respective pressure generating chambers with a vibration plate therebetween. Each piezoelectric element includes a piezoelectric layers disposed between a first electrode and a second electrode. Anti-deformation layers continue from the piezoelectric layers and contain a less moisture-permeable component than the piezoelectric layer. The piezoelectric layers and the anti-deformation layers are alternately and continuously disposed in the direction of the arrangement of the rows of the pressure generating chambers. The anti-deformation layers are disposed at least in regions opposing the partition member with the vibration plate therebetween. Each piezoelectric layer is enclosed by the first electrode, the second electrode and at least either the vibration plate or the anti-deformation layer.

Other features and objects of the invention will become apparent from the following description in the specification and accompanying drawings.

### BRIEF DESCRIPTION OF THE DRAWINGS

For more completely understanding the invention and advantages thereof, see the following description and the following accompanying drawings.

FIG. 1 is a schematic representation of an ink jet recording apparatus according to an embodiment.

FIG. 2 is a fragmentary exploded perspective view showing an ink jet recording head.

FIG. 3 (a) is a fragmentary plan view of the ink jet recording head, and (b) is a sectional view of the ink jet recording head.

FIG. 4 (a) is a fragmentary sectional view taken along line A-A in FIG. 3(a), and FIG. 4(b) is a sectional view taken along line B-B in FIG. 3(a).

FIG. 5 is a flow chart of a process for forming a piezoelectric element.

FIGS. 6 (a) to (c) are representations of the step of forming a lower electrode; (d) is a representation of the step of forming a piezoelectric layer; (e) is a representation of the step of etching the piezoelectric layer; and (f) is a representation of the step of forming an anti-deformation layer.

FIGS. 7 (g) to (h) are representations of the step of forming the anti-deformation layer; (i) is a representation of the step of forming the anti-deformation layer; and (j) and (k) are representations of the step of forming an upper electrode.

FIGS. 8 (l) and (m) are representations of the step of forming an insulator layer; (n) and (o) are representations of the step of forming an upper electrode lead; and (p) is a representation of the step of etching a flow channel substrate.

### DETAILED DESCRIPTION OF PREFERRED EMBODIMENTS

At least the following will become apparent from the description in the specification and the accompanying drawings:

A liquid jet head includes: rows of pressure generating chambers communicating with respective nozzle apertures; a partition member separating the pressure generating chambers from each other; and piezoelectric elements opposing the respective pressure generating chambers with a vibration plate therebetween. Each piezoelectric element includes a piezoelectric layer disposed between a first electrode and a second electrode. Anti-deformation layers continue from the piezoelectric layers and contain a less moisture-permeable component than the piezoelectric layer. The piezoelectric layers and the anti-deformation layers are alternately and continuously disposed in the direction of the arrangement of the rows of the pressure generating chambers. The anti-deformation layers are disposed at least in regions opposing the partition member with the vibration plate therebetween. Each piezoelectric layer is enclosed by the first electrode, the second electrode and at least either the vibration plate or the anti-deformation layer.

In this version, the piezoelectric layer is enclosed by the first electrode and second electrode, which constitute the piezoelectric layer, and at least either the vibration plate or the anti-deformation layer continuing from the piezoelectric layer and containing a less moisture permeable component than the piezoelectric layer. Consequently, a liquid jet head can be provided in which the adhesion and penetration of moisture to the piezoelectric layer are reduced to reduce defects, such as short circuit.

Also, since no member is formed in the piezoelectric element except the components of the piezoelectric element, the reduction in displacement of the vibration plate can be prevented.

In addition, since the anti-deformation layer is formed at least in regions corresponding to the partition member so as to continue from the piezoelectric layer, and contains a less moisture permeable component than the piezoelectric layer, the vibration of the vibration plate caused by the piezoelectric element can be reduced at the partition member and its vicinity. Consequently, in the resulting liquid jet head, the occurrence of cracks in the vibration plate resulting from the vibration of the vibration plate is reduced at the partition member and its vicinity.

The above liquid jet head wherein each anti-deformation layer is partially covered with an insulator layer made of an inorganic insulating material.

In this version, since part of the anti-deformation layer is covered with the insulator layer of an inorganic insulating material, the penetration of moisture from the anti-deformation layer is further reduced. In the liquid jet head, consequently, defects, such as short circuit, are further reduced.

A liquid jet apparatus including the above liquid jet head.

This version can provide a liquid jet apparatus producing the above effects.

A method of manufacturing a liquid jet head including rows of pressure generating chambers, a partition member separating the pressure generating chambers from each other, and piezoelectric elements opposing the respective pressure generating chambers with a vibration plate therebetween. The method includes: the step of forming a first electrode on the vibration plate; the step of forming a piezoelectric layer on the vibration plate and the first electrode over the arrangement of rows of the pressure generating chambers; the step of forming anti-deformation layers by applying deformation restraining treatment to the piezoelectric layer in at least regions opposing the partition member with the vibration plate therebetween; and the step of forming a second electrode on the piezoelectric layer.

In this version, the piezoelectric layer of the piezoelectric element is enclosed by the first electrode and second electrode, which constitute the piezoelectric element, and at least either the vibration plate or the anti-deformation layer. Consequently, a method of manufacturing a liquid jet head can be provided which reduces the adhesion and penetration of moisture to or into the piezoelectric layer and thus reduces defects, such as short circuit.

Also, since no member is formed in the piezoelectric element except the components of the piezoelectric element, the reduction in displacement of the vibration plate can be prevented.

Furthermore, since the anti-deformation layer is formed at least in regions corresponding to the partition member, the vibration of the vibration plate caused by the piezoelectric element can be reduced at the partition member and its vicinity. Therefore, the stress produced in the vibration plate between the portion fixed to the partition member and the portion that can vibrate is reduced. Thus, a method of manufacturing a liquid jet head can be provided which reduces the occurrence of cracks in the vibration plate.

The above liquid jet head manufacturing method further including the step of forming an insulator layer of an inorganic insulating material on the surface of the anti-deformation layer after the step of forming the second electrode.

In this version, since part of the anti-deformation layer is covered with the insulator layer of an inorganic insulating material, the penetration of moisture from the anti-deformation layer is further reduced. The liquid jet head manufacturing method further reduces defects, such as short circuit.

The liquid jet head manufacturing method, wherein the deformation restraining treatment is performed by ion implantation.

This version can provide a liquid jet head manufacturing method in which the anti-deformation layer can be easily formed by changing the composition or the structure of the previously formed piezoelectric layer by ion implantation, and in which regions where the anti-deformation layers are formed can be selected.

A preferred embodiment of the invention will now be described with reference to the drawings. The below-described embodiment is a version of the present invention, and all the components described are not necessarily required.

### BEST MODE OF THE INVENTION

Embodiments will now be described with reference to the drawings.

### Embodiment 1

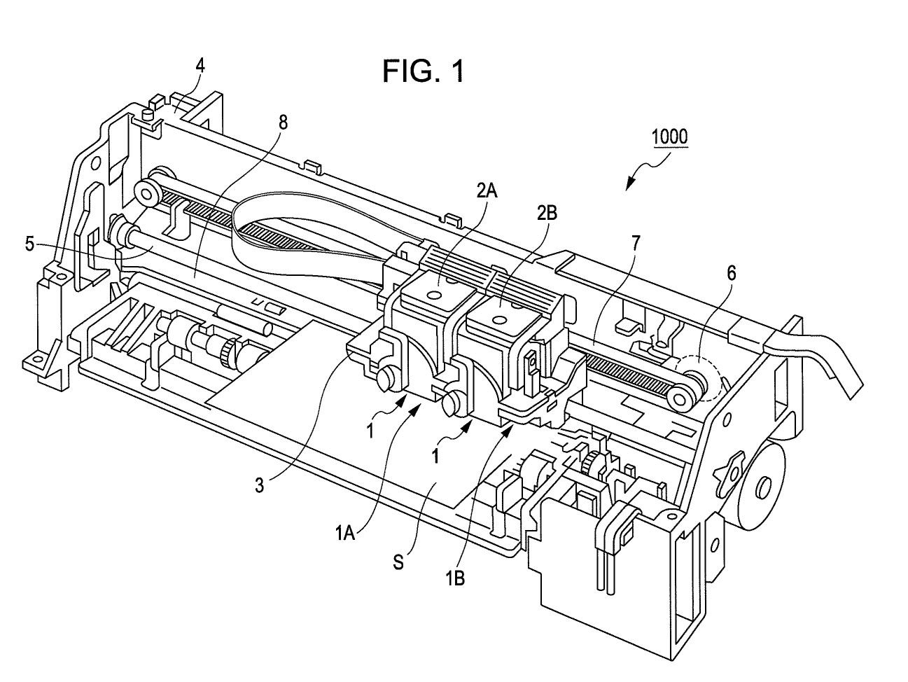

FIG. 1 is a schematic representation of an ink jet recording apparatus 1000 according to the present embodiment, which is a version of the liquid jet apparatus.

As shown in FIG. 1, the ink jet recording apparatus 1000 includes recording head units 1A and 1B.

The recording head units 1A and 1B include removable cartridges 2A and 2B defining ink supply means, respectively, and are mounted on a carriage 3. The carriage 3 is secured to a carriage shaft 5 provided to a device body 4, and is movable in the shaft direction.

The recording head units 1A and 1B eject, for example, a black ink composition and a color ink composition, respectively. The carriage 3 on which the recording head units 1A and 1B are mounted is moved along the carriage shaft 5 by transmitting the driving force from a driving motor 6 to the carriage 3 with a plurality of gears (not shown) and a timing belt 7. In the apparatus body 4, a platen 8 is disposed along the carriage shaft 5 so that a recording sheet S being a print medium, such as paper, fed from a paper feed roller or the like (not shown) is transported over the platen 8.

The recording head units 1A and 1B each have an ink jet recording head 1 being a liquid jet head opposing the recording sheet S.

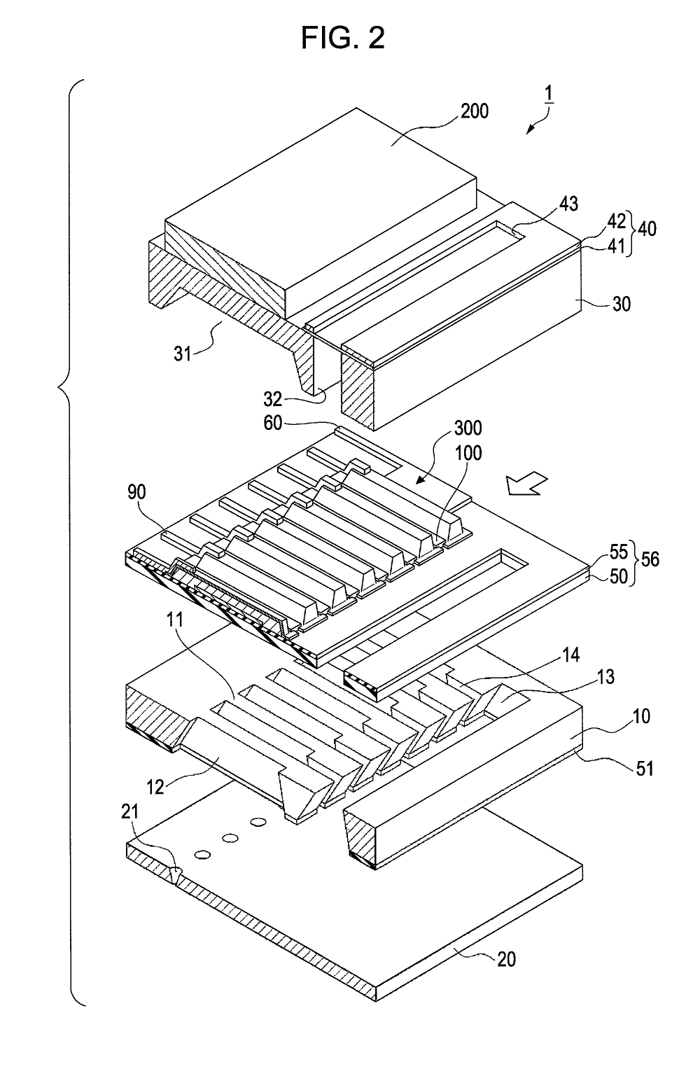

FIG. 2 is a fragmentary exploded perspective view of the ink jet recording head 1 according to the present embodiment. The ink jet recording head 1 is in a shape of substantially rectangular solid, and FIG. 2 is a fragmentary exploded perspective view of the ink jet recording head 1 cut along a plane perpendicular to the longitudinal direction thereof (the direction of the white hollow arrow).

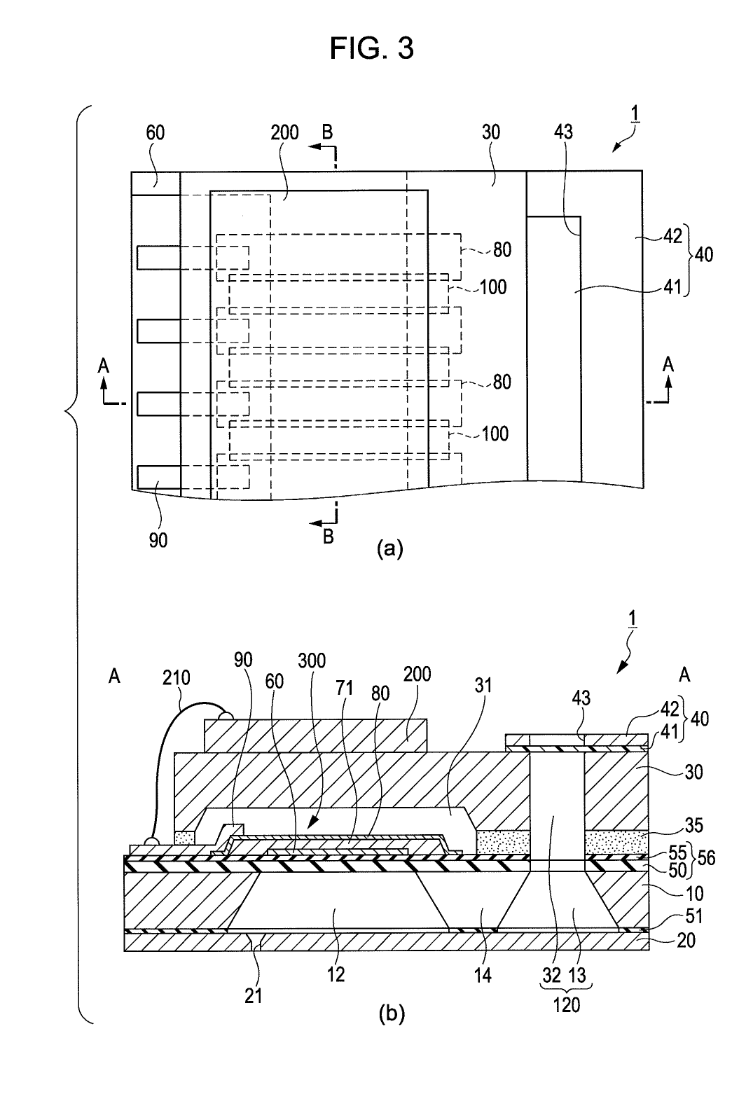

FIG. 3(a) is a fragmentary plan view of the ink jet recording head 1, and FIG. 3(b) is a fragmentary sectional view taken along line A-A in FIG. 3(a).

The ink jet recording head 1 shown in FIGS. 2 and 3 includes a flow channel substrate 10, a nozzle plate 20, a joining substrate 30, a compliance substrate 40 and a driving IC 200.

The flow channel substrate 10, the nozzle plate 20 and the joining substrate 30 are stacked in such a manner that the flow channel substrate 10 is disposed between the nozzle plate 20 and the joining substrate 30, and the compliance substrate 40 is disposed on the joining substrate 30. Also, the driving IC 200 is disposed on the compliance substrate 40.

The flow channel substrate 10 is made of a (110) plane-oriented silicon single crystal plate. The flow channel substrate 10 has a plurality of pressure generating chambers 12 are formed by anisotropic etching and separated by a partition member 11. The pressure generating chambers 12 are arranged in rows in the longitudinal direction. The cross section of the pressure generating chamber 12 perpendicular to the longitudinal direction of the ink jet recording head 1 has a trapezoidal shape. The pressure generating chambers 12 extend long in the width direction of the ink jet recording head 1. The flow channel substrate 10 and the joining substrate 30 are bonded to each other with an adhesion layer 35.

An ink supply channel 13 is formed at one ends in the width direction of the pressure generating chambers 12 of the flow channel substrate 10, and communicates with the pressure generating chambers 12 through respective communicating sections 14. Each communicating section 14 has a smaller width than the pressure generating chamber 12, so that the flow channel resistance of the ink delivered to the pressure generating chamber 12 from the communicating section 14 is kept constant.

The nozzle plate 20 has nozzle apertures 21 therein to communicate with the vicinity of the ends of the pressure generating chambers 12 opposite the ink supply channel 13.

The nozzle plate 20 is made of a glass ceramic plate, a silicon single crystal substrate, a stainless steel plate or the like having a thickness of, for example, 0.01 to 1 mm and a linear expansion coefficient of, for example, 2.5 to 4.5[×10⁻⁶/° C.] at 300° C. or less.

The flow channel substrate 10 and the nozzle plate 20 are bonded to each other with an insulating protective film 51 therebetween using an adhesive, thermal fusion film or the like. The insulating protective film 51 has been used as a mask for forming the pressure generating chambers 12 by anisotropic etching.

An elastic film 50 defining a vibration plate is formed on the surface of the flow channel substrate 10 opposite the surface bonded to the nozzle plate 20. The elastic film 50 includes an oxide film formed by thermal oxidation. The elastic film 50 of the flow channel substrate 10 is covered with an oxide insulating film 55.

On the insulating film 55 are formed a lower electrode 60 acting as a first electrode made of a metal, such as platinum (Pt), or a metal oxide, such as strontium ruthenate (SrRuO), a piezoelectric layer 71 having a perovskite structure, and upper electrode 80 acting as a second electrode made of a metal, such as Au or Ir. These electrodes and layer constitute a piezoelectric element 300. The piezoelectric element 300 mentioned herein refers to the portion including the lower electrode 60, the piezoelectric layer 71 and the upper electrode 80.

The piezoelectric layer 71 can be made of a ferroelectric piezoelectric material, such as lead zirconate titanate (PZT), or a relaxer ferroelectric material prepared by, for example, adding a metal, such as niobium, nickel, magnesium, bismuth or yttrium, to a ferroelectric piezoelectric material. The composition of the piezoelectric layer may be appropriately selected in view of the characteristics and application of the piezoelectric element 300.

In general, either electrode of the piezoelectric element 300 acts as a common electrode, and the other electrode is formed for each pressure generating chamber 12 by patterning. Also, the electrode formed by patterning and the piezoelectric layer 71 define a piezoelectric active portion at which piezoelectric distortion is caused by applying a current to both electrodes.

Although in the present embodiment, the lower electrode 60 acts as the common electrode of the piezoelectric element 300 and the upper electrode 80 acts as discrete electrodes of the piezoelectric elements 300, the functions of the lower and upper electrodes may be reversed for the sake of convenience of the driving circuit and the wiring. In either case, the piezoelectric active portion is provided for each pressure generating chamber 12. In the present embodiment, the piezoelectric element 300 and the set of the elastic film 50 and the insulating film 55 (the set is referred to as vibration plate 56) where displacement occurs by driving the piezoelectric element 300 define a piezoelectric actuator.

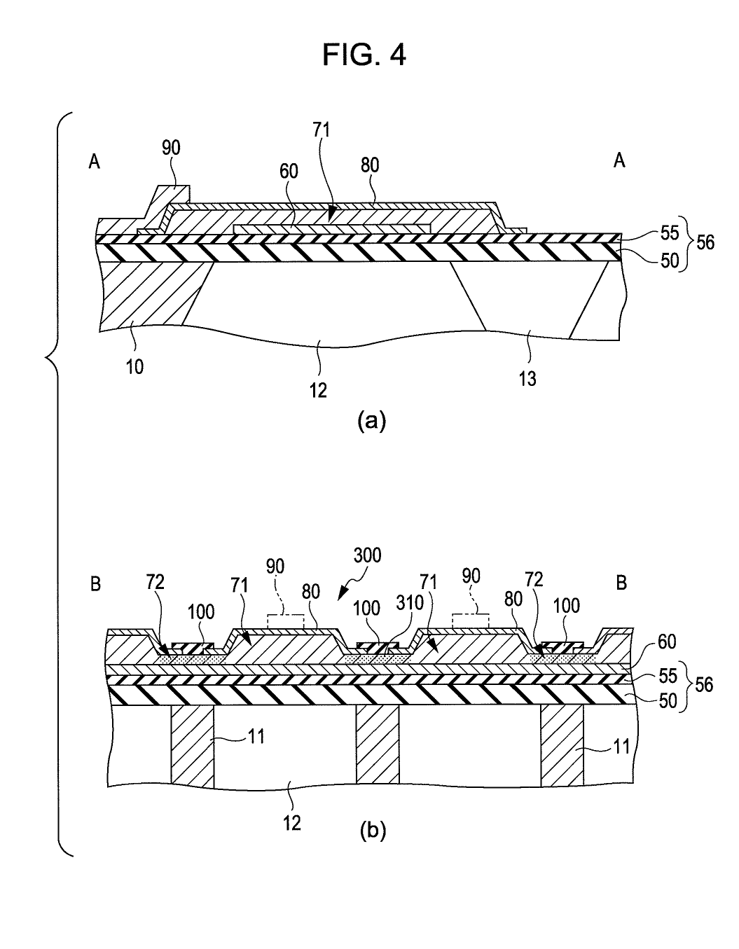

FIG. 4 shows enlarged sectional views of the piezoelectric actuator and its vicinity. FIG. 4(a) is a fragmentary sectional view taken along line A-A in FIG. 3(a), and FIG. 4(b) is a sectional view taken line B-B in FIG. 3(a).

The structure around the piezoelectric actuator will now be described in detail with reference to FIG. 4.

Referring to FIGS. 3 and 4(a), the piezoelectric layer 71 is formed in a rectangular shape and extends along the corresponding pressure generating chamber 12. The lower electrode 60 has a smaller width than the pressure generating chamber 12.

The piezoelectric layer 71 is enclosed by the vibration plate 56, the lower electrode 60 and the upper electrode 80.

Referring to FIG. 4(b), anti-deformation layers 72 are disposed along the partition member 11 separating the pressure generating chambers 12 (in the direction perpendicular to the sheet of the figure), continuing from the piezoelectric layers 71. The anti-deformation layer 72 is thinner than the piezoelectric layer 71, and is disposed in a region opposing the partition member 11 with the vibration plate 56 therebetween. The anti-deformation layer continues from the piezoelectric layer 71 and contains a component that is less moisture-permeable than the piezoelectric layer 71. In the present embodiment, the anti-deformation layer 72 has a larger width than the partition member 11, and extends to the region overlap the pressure generating chamber 12. Thus, the piezoelectric layers 71 and the anti-deformation layers 72 are alternately disposed over the pressure generating chambers 12 arranged in the longitudinal direction of the ink jet recording head 1.

The anti-deformation layer 72 contains oxygen, boron, sulfur or the like in addition to the same components as the piezoelectric layer 71, and is thus more restrained than the piezoelectric layer 71 from being deformed by current application between the lower electrode 60 and the upper electrode 80.

The piezoelectric layer 71 is enclosed by the vibration plate 56, the lower electrode 60, the upper electrode 80 and the anti-deformation layer 72.

Since the upper electrode 80 is formed as discrete electrodes, the anti-deformation layers 72 each have a portion not covered with the upper electrode 80. Insulator layers 100 are formed on such portions along the partition member 11. The insulator layer 100 can be made of any inorganic insulating material without particular limitation, such as aluminium oxide (AlOₓ) or tantalum oxide (TaOₓ), and is preferably made of less moisture-permeable aluminium oxide.

As shown in FIGS. 2 and 3, upper electrode leads 90 made of gold (Au) or the like are connected to the respective upper electrodes 80 of the piezoelectric elements 300.

The joining substrate 30 on which a driving IC 200 for driving the piezoelectric elements 300 is to be mounted is bonded on the flow channel substrate 10 having the piezoelectric elements 300.

The joining substrate 30 has a piezoelectric element-protecting section 31 in the region opposing the piezoelectric elements 300. The piezoelectric element-protecting section 31 can be sealed maintaining a space not interfering with the movement of the piezoelectric elements 300. The piezoelectric element-protecting section 31 is provided according to the rows of the pressure generating chambers 12.

Although the piezoelectric element-protecting section 31 is integrally formed according to the arrangement of the rows of the pressure generating chambers 12 in the present embodiment, it may be formed separately for each piezoelectric element 300.

The joining substrate 30 is made of, for example, glass, ceramic material, metal or resin, and is preferably made of a material having substantially the same thermal expansion coefficient as the material of the flow channel substrate 10. In the present embodiment, the joining substrate is made of the same silicon single crystal substrate as the flow channel substrate 10.

The joining substrate 30 also has a reservoir section 32 in the region corresponding to the ink supply channel 13 of the flow channel substrate 10. The reservoir section 32 passes through the thickness of the joining substrate 30 and extends along the arrangement of the rows of the pressure generating chambers 12. Thus, the reservoir section 32 communicates with the ink supply channel 13 of the flow channel substrate 10 to form the reservoir 120 acting as the common ink chamber of the pressure generating chambers 12.

In addition, a wiring pattern is formed on the joining substrate 30, and external wires (not shown) are connected to the wiring pattern to supply driving signals. Then, a driving IC 200, or semiconductor integrated circuit (IC), for driving the piezoelectric elements 300 is mounted on the wiring pattern.

The driving signals include a signal for driving the driving IC 200, such as driving powder source signal, and control signals, such as serial signals (SI), and the wiring pattern includes a plurality of wires to which signals are supplied.

The lower electrode 60 is continuously formed in the region corresponding to the plurality of pressure generating chambers 12, opposing the pressure generating chambers 12 in the longitudinal direction of the pressure generating chamber 12. The lower electrode 60 extends to the outside beyond the arrangement of the pressure generating chambers 12.

The upper electrode leads 90 are connected to one ends of the upper electrodes 80. The upper electrode leads 90 extending from the piezoelectric elements 300 are each electrically connected to the driving IC 200 with, for example, a connection wire 210 including an electroconductive wire, such as a bonding wire. Similarly, the driving IC 200 and the lower electrode 60 are electrically connected to each other with a connection wire (not shown).

Furthermore, a compliance substrate 40 including a sealing film 41 and a fixing plate 42 is joined on the joining substrate 30. The sealing film 41 is made of a flexible material having a low rigidity (for example, a 6 μm thick polyphenylene sulfide (PPS) film). The sealing film 41 seals one side of the reservoir section 32. The fixing plate 42 is made of a hard material, such as metal, (for example, a 30 μm thick stainless steel (SUS)). The portion of the fixing plate 42 opposing the reservoir 120 is completely removed in the thickness direction to form an opening 43; hence only the flexible sealing film 41 is present at one side of the reservoir 120.

A method of manufacturing the ink jet recording head 1 will now be described.

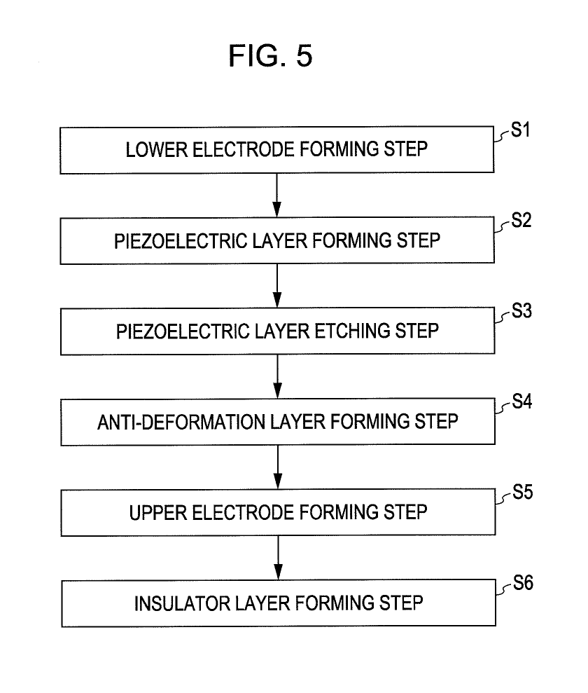

FIG. 5 is a flow chart of a piezoelectric element forming process included in the method of manufacturing the ink jet recording head 1. For obtaining the ink jet recording head 1, a plurality of ink jet recording heads 1 are formed in a wafer and are separated from each other by cutting.

The piezoelectric element forming process includes: Step 1 (S1) that is the step of forming a lower electrode or a first electrode; Step 2 (S2) that is the step of forming a piezoelectric layer; Step 3 (S3) that is the step of etching the piezoelectric layer; step 4 (S4) that is the step of forming a anti-deformation layer; Step 5 (S5) that is the step of forming an upper electrode or a second electrode; and Step 6 (S6) that is the step of forming an insulator layer.

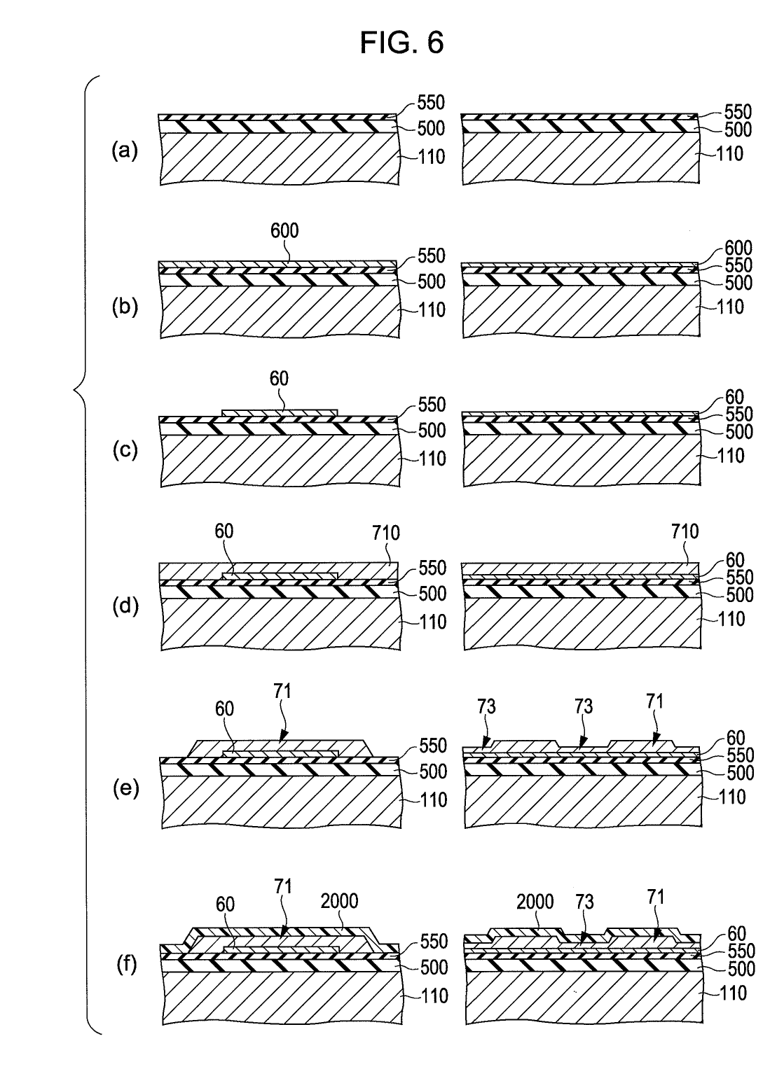

FIGS. 6(a) to 8(p) each show two sectional views of the corresponding step. The left sectional views correspond to the sectional view are taken along line A-A in FIG. 3(a), and the right sectional views correspond to the sectional view taken along line B-B in FIG. 3(a).

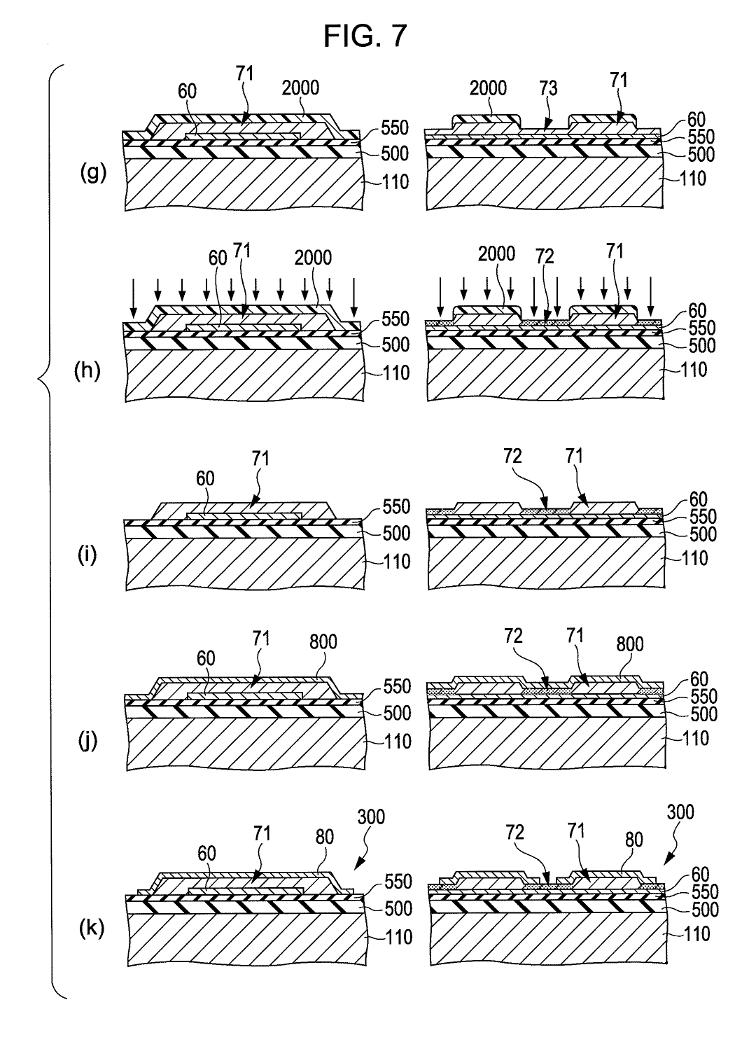

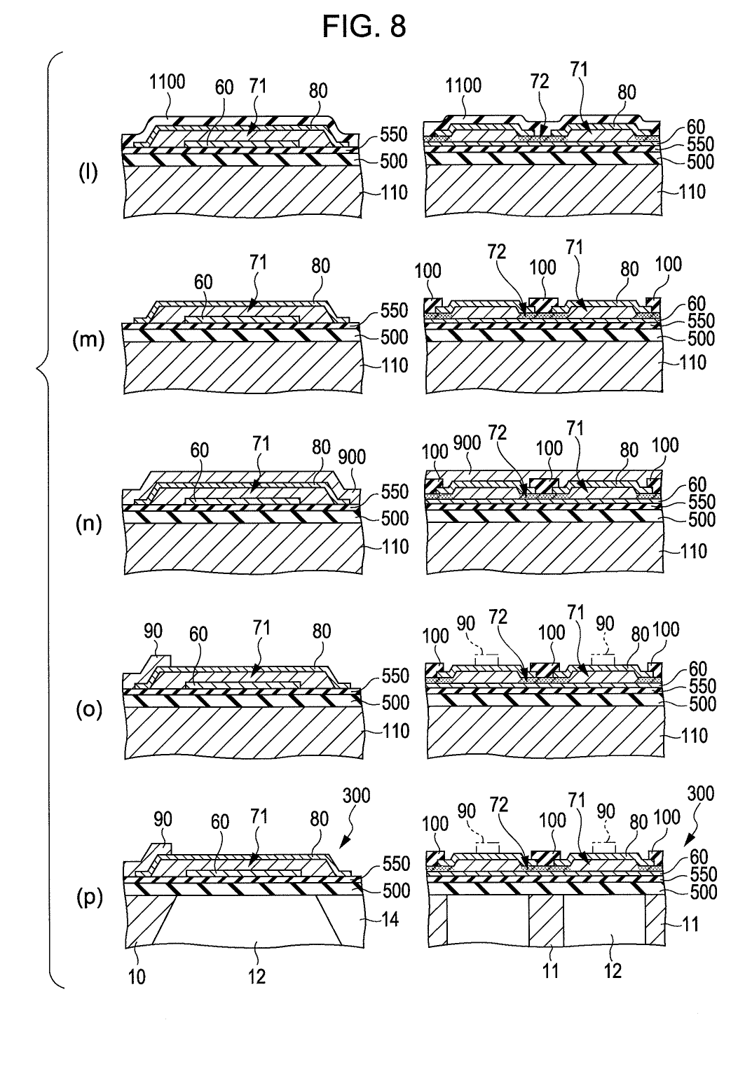

FIGS. 6(a) to 6(c) show the lower electrode forming step (S1); FIG. 6(d) shows the piezoelectric layer forming step (S2); FIG. 6(e) shows the piezoelectric layer etching step (S3); FIGS. 6(f) to 7(i) show the anti-deformation layer forming step (S4); FIGS. 7(j) and 7(k) show the upper electrode forming step (S5); and FIGS. 8(l) to 8(m) show the insulator layer forming step (S6). FIGS. 8(n) and 8(o) show an upper electrode lead forming step; and FIG. 8(p) shows a flow channel substrate etching step.

In FIG. 6(a), a silicon wafer substrate 110 is subjected to high-temperature treatment in an oxidizing atmosphere containing oxygen or water vapor to form an elastic film 500 of, for example, silicon oxide at the surface of the silicon wafer substrate 110. The elastic film 500 may be formed by CVD (Chemical Vapor Deposition) instead of thermal oxidation. On the elastic film 500, an insulating film 550 is formed of zirconium oxide or the like. The insulating film 550 can be formed by sputtering, vacuum vapor deposition or the like.

Turning to FIG. 6(b), a lower electrode layer 600 containing iridium (Ir) or the like or a metal oxide, such as strontium ruthenate (SrRuO), is formed on the insulating film 550. First, for example, a layer containing iridium (Ir) is formed, subsequently a layer containing platinum (Pt) is formed, and further a layer containing iridium (Ir) is formed. Each layer constituting the lower electrode layer 600 is formed by depositing iridium (Ir) or platinum (Pt) on the surface of the insulating film 550 by sputtering or the like. Preferably, a titanium (T) or chromium (Cr) adhesion layer (not shown) is formed by sputtering or vacuum vapor deposition before forming the lower electrode layer 600.

Turning to FIG. 6(c), the lower electrode layer 600 is etched into lower electrodes 60 acting as first electrodes of the respective ink jet recording heads 1. The etching can be performed by a generally known technique, such as dry etching or wet etching.

In FIG. 6(d), a piezoelectric precursor film is formed by a sol-gel method. First, a sol of an organic metal alkoxide solution is applied onto the insulating film 550 and the lower electrode 60 by spin coating or the like. Subsequently, the coating is dried at a predetermined temperature for a predetermined time period to vaporize the solvent. After being dried, the coating is degreased in the atmosphere at a predetermined temperature for a predetermined time period so that the organic ligands coordinating with the metal are thermally decomposed to produce a metal oxide. By repeating the sequence of coating, drying and degreasing a predetermined number of times, for example, twice, a two-layer piezoelectric precursor film is formed. The drying and degreasing allow the metal alkoxide and acetate in the solvent to form a metal-oxygen-metal network through thermal decomposition of the ligands. This step may be performed by MOD (Metal Organic Deposition) without being limited to the sol-gel method.

After the formation of the piezoelectric precursor film, the piezoelectric precursor film is crystallized by firing. The piezoelectric precursor film is changed to a crystal structure from an amorphous state by firing, and is thus turned into a piezoelectric layer 710 exhibiting an ability of electromechanical conversion.

Turning to FIG. 6(e), the piezoelectric layer 710 is patterned into a shape shown in FIG. 4 by etching, thus forming the piezoelectric layers 71 and thin portions 73 of the piezoelectric layers 71. The thin portions 73 are formed at least in regions corresponding to the partition member 11 shown in FIG. 4. In the present embodiment, the thin portions 73 reach the pressure generating chambers 12. The piezoelectric layers 71 and the thin portions 73 can be formed by using a mask and controlling the etching time.

In FIG. 6(f), a resist 2000 is applied over the piezoelectric layers 71 and the thin portions 73 by spin coating.

In FIG. 7(g), the resist 2000 is patterned to expose the thin portions 73.

In FIG. 7(h), the thin portions 73 are doped by ion implantation using the resist 2000 as a mask, thereby forming anti-deformation layers 72. The anti-deformation layers 72 continue from the piezoelectric layers 71 and contain a component that is less moisture-permeable than the piezoelectric layers 71. More specifically, an element contained in the piezoelectric layer 71 is added to the anti-deformation layer 72 to a higher content than the content in the piezoelectric layer 71, and/or an element not contained in the piezoelectric layer 71 is added to the anti-deformation layer 72. Thus, the anti-deformation layers 72 are formed, which are regions less moisture-permeable than the piezoelectric layers 71.

In order to dope the anti-deformation layer 72 with such dopant (constituent), for example, ion implantation is performed using at least one selected from the group consisting of, for example, oxygen atom (O), nitrogen atom (N), argon atom (Ar), carbon atom (C), phosphorus atom (P) and boron atom (B). The ion implantation can be performed under conditions of, for example, 100 keV to 1 MeV and a dose of 1×10 E19 to 1×10 E21/cm².

The regions where dopant has been introduced become anti-deformation layers 72 whose deformation is more restrained than the deformation of the piezoelectric layer 71 according to the dose. The regions other than the anti-deformation layers 72 act as the piezoelectric layers 71 exhibiting desired piezoelectric characteristics. Thus, the anti-deformation layer 72 and the piezoelectric layer 71 differ in displacement at the same applied voltage.

Turning to FIG. 7(i), the resist 2000 is removed.

In FIG. 7(j), an upper electrode layer 800 is formed on the piezoelectric layers 71 and the anti-deformation layers 72 by electron beam vapor deposition or sputtering.

In FIG. 7(k), the upper electrode layer 800 is patterned so as to partially expose the anti-deformation layers 72 by etching, thus forming discrete upper electrodes 80. At this point, piezoelectric elements 300, each including the lower electrode 60, the piezoelectric layer 71 and the upper electrode 80 are completed.

Turning to FIG. 8(l), an insulator layer film 1100 is formed. Insulator layer film 1100 can be formed by, for example, CVD. For forming the insulator layer film 1100, desired properties, such as film density and Young's modulus, can be relatively easily imparted to the insulator layer film 1100 by controlling some conditions, such as temperature and gas flow rate.

In FIG. 8(m), the insulator layer film 1100 is etched such that the portions covering the anti-deformation layers 72 remain, thus forming the insulator layers 100.

In FIG. 8(n), the upper electrode lead layer 900 is formed on the upper electrodes 80 and the insulator layers 100.

In FIG. 8(o), the upper electrode lead layer 900 is etched into the shape shown in FIGS. 2 and 3, thus forming the upper electrode leads 90.

In FIG. 8(p), the surface of the flow channel substrate 10 opposite to the surface on which the piezoelectric elements 300 have been formed is subjected to anisotropic etching or anisotropic etching using an active gas such as parallel plate reactive ion etching to form pressure generating chambers 12. The remaining portion not etched is used as the partition member 11 defining the pressure generating chambers 12.

Then, a nozzle plate 20 having nozzle apertures 21 therein is bonded to the flow channel substrate 10, and a compliance substrate 40 that is a composite of a PPS film acting as a flexible sealing film 41 and a SUS film acting as a fixing plate 42 made of a metal is bonded so as to cover the reservoir 32 of the joining substrate. Thus, the ink jet recording head as shown in FIG. 3(b) according to the present embodiment is completed.

The ink jet recording head 1 can be manufactured in a process including the above-described steps.

According to the embodiment, the following effects are produced.

Since the piezoelectric layer 71 is enclosed by the lower electrode 60 and upper electrode 80, which constitute the piezoelectric element 300, and at least either the vibration plate 56 or the anti-deformation layer 72, the adhesion and penetration of moisture to or into the piezoelectric layer 71 can be reduced. Consequently, the above embodiment provides an ink jet recording head 1, an ink jet recording apparatus 1000 and a method of manufacturing the ink jet recording head 1 that can reduce defects, such as short circuit.

Also, since no member is formed in the piezoelectric element 300 except the components of the piezoelectric element 300, the reduction in displacement of the vibration plate 56 can be prevented.

In addition, since the anti-deformation layer 72 is formed at least in regions corresponding to the partition member 11, the vibration of the vibration plate 56 caused by the piezoelectric element 300 can be reduced at the partition member 11 and its vicinity. Consequently, the above embodiment provides an ink jet recording head 1, an ink jet recording apparatus 1000 and a method of manufacturing the ink jet recording head 1 that can reduce the occurrence of cracks in the vibration plate 56 resulting from the vibration of the vibration plate 56 at the partition member 11 and its vicinity.

(2) Since part of the anti-deformation layer 72 is covered with the insulator layer 100 made of an inorganic insulating material, the penetration of moisture from the anti-deformation layer 72 can further be reduced. Consequently, the above embodiment can provide an ink jet recording head 1, an ink jet recording apparatus 1000 and a method of manufacturing the ink jet recording head 1 that can reduce defects, such as short circuit.

(3) Since the anti-deformation layer 72 is covered with less moisture-permeable aluminum oxide, the penetration of moisture from the anti-deformation layer 72 can further be reduced. Consequently, the above embodiment can provide an ink jet recording head 1, an ink jet recording apparatus 1000 and a method of manufacturing the ink jet recording head 1 that can reduce defects, such as short circuit.

(4) A method of manufacturing the ink jet recording head 1 can be provided in which the anti-deformation layer 72 can easily be formed by changing the composition or the structure of the previously formed piezoelectric layer 71 by ion implantation, and in which a region where the anti-deformation layer is formed can be selected.

Although an embodiment has been described above, the invention is not limited to the above embodiment.

For example, in the above embodiment, the piezoelectric elements 300 are formed in the piezoelectric element-protecting section 31 of the joining substrate 30. However, the piezoelectric elements 300 may be exposed without being limited to the above structure. Since the piezoelectric layer 71 is enclosed by the lower electrode 60, the upper electrode 80 and at least either the vibration plate 56 or the anti-deformation layer 72 even in this case, the piezoelectric layer 71 can be reliably prevented from being broken by water (moisture).

Two rows of the pressure generating chambers 12 may be formed so that two sets of arrangements of the piezoelectric elements 300 or the like are symmetrically disposed with the upper electrode leads 90 of the ink jet recording head 1 between the arrangements.

Although the joining substrate 30 of the above embodiment has a piezoelectric element-protecting section 31, the joining substrate is not particularly limited as long as it is a substrate onto which a driving IC 200 is mounted.

If the anti-deformation layer 72 is sufficiently water-resistant, the insulator layer 100 is not necessarily required.

The above embodiment has described an ink jet recording head as one version of the liquid jet head of the present invention, and the fundamental structure of the liquid jet head is not limited to the above-described one. The present invention is intended for all liquid jet heads widely, and can of course be applied to a device ejecting liquid other than ink. Other liquid jet heads include various types of recording heads used in image recording apparatuses such as printers, color material jet heads used for manufacturing color filters of liquid crystal displays or the like, electrode material jet heads used for forming electrodes of organic EL displays or FEDs (field emission displays), and bioorganic material jet heads used for manufacturing bio-chips.

1. A liquid jet head comprising:
rows of pressure generating chambers communicating with respective nozzle apertures;
a partition member separating the pressure generating chambers from each other; and
piezoelectric elements opposing the respective pressure generating chambers with a vibration plate therebetween,
wherein the piezoelectric elements each include a piezoelectric layer disposed between a first electrode and a second electrode, anti-deformation layers continue from the piezoelectric layers and contain a less moisture-permeable component than the piezoelectric layer, and the piezoelectric layers and the anti-deformation layers are alternately and continuously disposed in the direction of the arrangement of the rows of the pressure generating chambers,
wherein the anti-deformation layers are disposed at least in regions opposing the partition member with the vibration plate therebetween, and
wherein each piezoelectric layer is enclosed by the first electrode, the second electrode and at least either the vibration plate or the anti-deformation layer.

2. The liquid jet head according to claim 1, wherein each anti-deformation layer is partially covered with an insulator layers made of an inorganic insulating material.

3. A liquid jet apparatus comprising the liquid jet head as set forth in claim 1.

4. A method of manufacturing a liquid jet head, the method comprising:
the step of forming a vibration plate on a substrate in which a flow channel is to be formed;
the step of forming a first electrode on the vibration plate;
the step of forming a piezoelectric layer on the vibration plate and the first electrode over the arrangement of rows of the pressure generating chambers;
the step of forming anti-deformation layers by applying treatment for restraining deformation to the piezoelectric layer in at least regions opposing the partition member with the vibration plate therebetween; and
the step of forming a second electrode on the piezoelectric layer.

5. The liquid jet head manufacturing method according to claim 4, further comprising:
the step of forming an insulator layer of an inorganic insulating material on the surface of the anti-deformation layer after the step of forming the second electrode.

6. The liquid jet head manufacturing method according to claim 4, wherein the treatment for restraining deformation is performed by ion implantation.
